(19) United States
(12) Patent Application Publication
(10) Pub. No.: US 2008/0203461 A1
(43) Pub. Date: Aug. 28, 2008

(54) GATE STRUCTURE OF NAND FLASH MEMORY HAVING INSULATORS EACH FILLED WITH BETWEEN GATE ELECTRODES OF ADJACENT MEMORY CELLS AND MANUFACTURING METHOD THEREOF

(76) Inventors: Jungo Inaba, Yokohama-shi (JP); Mutsumi Okajima, Yokkaichi-shi (JP); Hiroshi Akahori, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/034,326

(22) Filed: Feb. 20, 2008

(30) Foreign Application Priority Data
Feb. 20, 2007 (JP) 2007-039757

(51) Int. Cl. H01L 29/788; H01L 21/336

(52) U.S. Cl. 257/316; 438/586; 257/E21.422; 257/E29.3

(57) ABSTRACT

A semiconductor device includes first and second gate electrodes arranged adjacent to each other, an oxide film formed between the first and second gate electrodes, and a nitride film formed on control gates and upper surfaces and sidewalls of the oxide film. Each of the first and second gate electrodes has a stacked gate structure which has a first insulating film, charge storage layer, second insulating film and control gate stacked on a semiconductor substrate. The uppermost surface of the oxide film is set higher than the uppermost surface of the control gate.

### CROSS-REFERENCE TO RELATED APPLICATIONS

This application is based upon and claims the benefit of priority from prior Japanese Patent Application No. 2007-039757, filed Feb. 20, 2007, the entire contents of which are incorporated herein by reference.

### BACKGROUND OF THE INVENTION

1. Field of the Invention

This invention relates to a semiconductor device and a manufacturing method thereof and, more particularly, to the gate structure of a NAND flash memory and a manufacturing method thereof and is applied to the technique for filling an insulator in between the gate electrodes of adjacent memory cells.

2. Description of the Related Art

In a NAND flash memory of a 70-nm generation, for example, as is disclosed in Jpn. Pat. Appln. KOKAI Publication 2003-197779, an insulator is filled in between the gate electrodes of adjacent memory cells to isolate the memory cells from each other. The gate structure is formed to electrically isolate word lines from each other and the insulator is filled in between the gate electrodes after formation of the gate electrodes.

In the next generation, for example, in a 50-nm generation or a generation of finer dimensions, a higher speed operation and higher integration density are required. In order to realize a next-generation NAND flash memory which satisfies the above requirement, it is indispensable to make narrower the pitch between the gate electrodes (between the word lines) of the memory cells. However, if the pitch between the gate electrodes is made narrower, various problems that the insulator cannot be sufficiently filled and the operation speed is lowered due to an increase in the wiring resistance and parasitic capacitance will occur. Therefore, it is desired to develop a new gate structure and a manufacturing method thereof.

### BRIEF SUMMARY OF THE INVENTION

According to one aspect of the present invention, there is provided a semiconductor device which includes first and second gate electrodes arranged adjacent to each other, each of the first and second gate electrodes having a stacked gate structure obtained by laminating a first insulating film, charge storage layer, second insulating film and control gate on a semiconductor substrate, an oxide film which is formed between the first and second gate electrodes and whose uppermost surface is set higher than an uppermost surface of the control gate, and a nitride film formed on the control gates, an upper surface of the oxide film and exposed sidewalls of the oxide film.

According to another aspect of the present invention, there is provided a manufacturing method of a semiconductor device which includes forming element isolation regions and active regions on a main surface of a semiconductor substrate, sequentially laminating a first insulating film, first conductive layer, second insulating film, second conductive layer and first nitride film on the active regions of the semiconductor substrate, forming a mask on the first nitride film and patterning the first nitride film, second conductive layer, second insulating film, first conductive layer and first insulating film to form a plurality of gate electrodes of gate electrode structures each having the first insulating film, charge storage layer, second insulating film, control gate and first nitride film sequentially stacked on the semiconductor substrate, forming an oxide film on the plurality of gate electrodes and between the plurality of gate electrodes, etching back the oxide film until surfaces of the first nitride films are exposed, forming an interlayer insulating film on the oxide films and first nitride films, making flat the surface to a depth until portions of the interlayer insulating film which lie between the plurality of gate electrodes are removed, removing the first nitride films by use of a chemical having a higher selective ratio with respect to the oxide films to expose surfaces of the control gates and set uppermost surfaces of the interlayer insulating film and oxide films higher than uppermost surfaces of the control gates, and forming a second nitride film on the first nitride films and upper surfaces and sidewalls of the oxide films.

### BRIEF DESCRIPTION OF THE SEVERAL VIEWS OF THE DRAWING

FIG. 1 is a plan view showing a pattern after formation of gate electrodes in memory cell portions, for illustrating a manufacturing process of a NAND flash memory which is a semiconductor device at a preceding stage leading to this invention;

FIG. 2 is a cross-sectional view taken along line X-X′ of FIG. 1 and showing a first manufacturing step of the NAND flash memory which is the semiconductor device at a preceding stage leading to this invention;

FIG. 3 is a cross-sectional view corresponding in position to the cross-sectional view taken along line X-X′ of FIG. 1 and showing a second manufacturing step of the NAND flash memory which is the semiconductor device at a preceding stage leading to this invention;

FIG. 4 is a cross-sectional view corresponding in position to the cross-sectional view taken along line X-X′ of FIG. 1 and showing a third manufacturing step of the NAND flash memory which is the semiconductor device at a preceding stage leading to this invention;

FIG. 5 is a cross-sectional view corresponding in position to the cross-sectional view taken along line X-X′ of FIG. 1 and showing a fourth manufacturing step of the NAND flash memory which is the semiconductor device at a preceding stage leading to this invention;

FIG. 6 is a cross-sectional view corresponding in position to the cross-sectional view taken along line X-X′ of FIG. 1 and showing a fifth manufacturing step of the NAND flash memory which is the semiconductor device at a preceding stage leading to this invention;

FIG. 7 is a cross-sectional view corresponding in position to the cross-sectional view taken along line X-X′ of FIG. 1 and showing a sixth manufacturing step of the NAND flash memory which is the semiconductor device at a preceding stage leading to this invention;

FIG. 8 is a cross-sectional view corresponding in position to the cross-sectional view taken along line X-X′ of FIG. 1 and showing a seventh manufacturing step of the NAND flash memory which is the semiconductor device at a preceding stage leading to this invention;

FIG. 9 is a cross-sectional view corresponding in position to the cross-sectional view taken along line X-X′ of FIG. 1 and showing a first manufacturing step after the step shown in FIG. 5, for illustrating a semiconductor device and a manufacturing method thereof according to an embodiment of this invention;

FIG. 10 is a cross-sectional view corresponding in position to the cross-sectional view taken along line X-X′ of FIG. 1 and showing a second manufacturing step, for illustrating the semiconductor device and the manufacturing method thereof according to the embodiment of this invention;

FIG. 11 is a cross-sectional view corresponding in position to the cross-sectional view taken along line X-X′ of FIG. 1 and showing a third manufacturing step, for illustrating the semiconductor device and the manufacturing method thereof according to the embodiment of this invention; and

FIG. 12 is a cross-sectional view corresponding in position to the cross-sectional view taken along line X-X′ of FIG. 1 and showing a fourth manufacturing step, for illustrating the semiconductor device and the manufacturing method thereof according to the embodiment of this invention.

### DETAILED DESCRIPTION OF THE INVENTION

First, a semiconductor device at a preceding stage leading to this invention and a manufacturing method thereof are explained and then an embodiment of this invention obtained by improving the above device and method is explained.

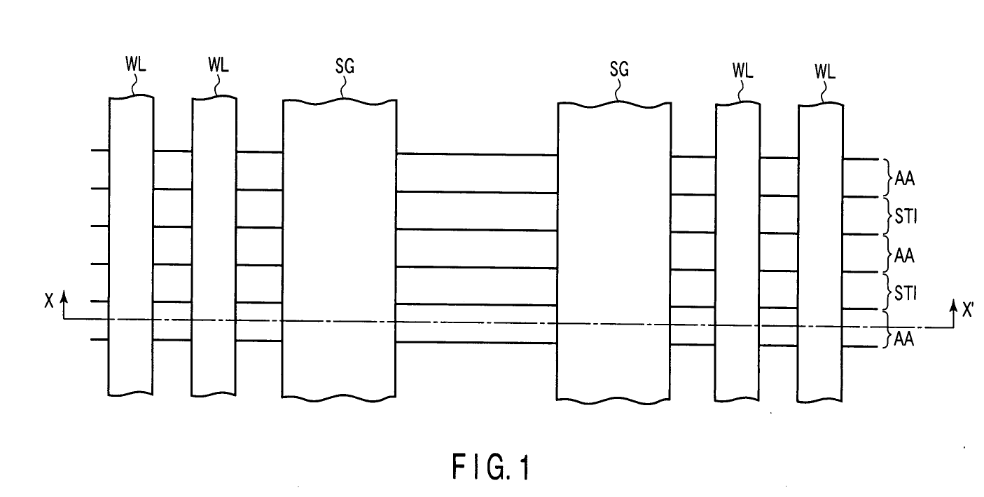

FIG. 1 is a plan view showing a pattern after formation of gate electrodes in memory cell portions and shows a state of an intermediate step of a manufacturing process of a NAND flash memory which is a semiconductor device at a preceding stage leading to this invention. In the memory cell portions, active regions (AA) and element isolation regions (STI) are alternately arranged and the adjacent active regions AA are electrically isolated from one another by the element isolation regions STI. Further, word lines WL which control gate voltages of cell transistors and select gates SG which select a page to be written are repeatedly arranged in a direction intersecting (perpendicular to) the extending direction of the above regions.

The above structure is formed as follows, for example. First, the active regions AA and element isolation regions STI are formed on the main surface of a semiconductor substrate by use of a well known ion-implantation technique and element isolation technique. Then, a tunnel insulating film (first insulating film), first-layer polysilicon layer (charge storage layer), inter-poly insulating film (second insulating film), second-layer polysilicon layer (control gate) and first nitride film are sequentially formed on the active regions AA of the main surface of the semiconductor substrate.

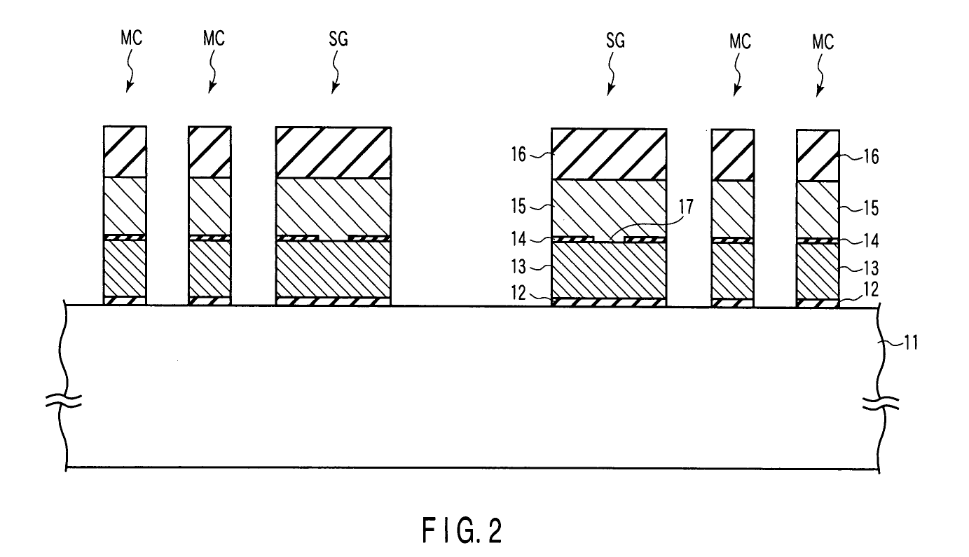

After this, a mask which is used to form gate electrodes is formed on the first nitride film to sequentially pattern the first nitride film, second-layer polysilicon layer, inter-poly insulating film, first-layer polysilicon layer and tunnel insulating film and form gate electrodes of memory cell portions MC and gate electrodes of select gate portions SG. Thus, the gate structures shown in FIG. 2 can be attained.

That is, each memory cell portion MC has a structure obtained by laminating a tunnel insulating film 12, a floating gate (FG) 13 acting as a charge storage layer, an inter-poly insulating film 14, a control gate (CG) 15 and a nitride film 16 on the main surface of a semiconductor substrate 11. Like the memory cell portion MC, each select gate portion SG has a structure obtained by laminating a tunnel insulating film 12, floating gate 13, inter-poly insulating film 14, control gate 15 and nitride film 16 on the semiconductor substrate 11. In each select gate portion SG, the floating gate 13 and control gate 15 are electrically connected via an opening 17 formed in the inter-poly insulating film 14. The opening 17 is formed after the inter-poly insulating film 14 is formed and before the second-layer polysilicon layer is stacked. The first- and second-layer polysilicon layers are thus connected and act as the gate electrode of a select gate transistor.

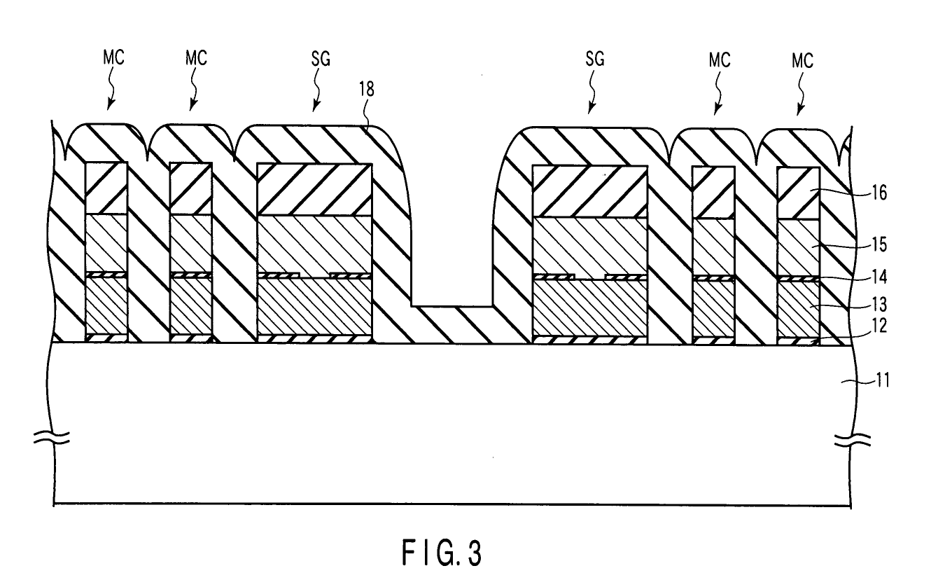

After this, as shown in FIG. 3, an oxide film (insulator) 18 is formed on the upper surfaces and sidewall portions of the stacked gate structures by use of the LP-CVD method. The oxide film 18 is used to fill in between the word lines so as to electrically isolate adjacent memory cells and control ion-implantation distances between the sources and drains of peripheral transistors.

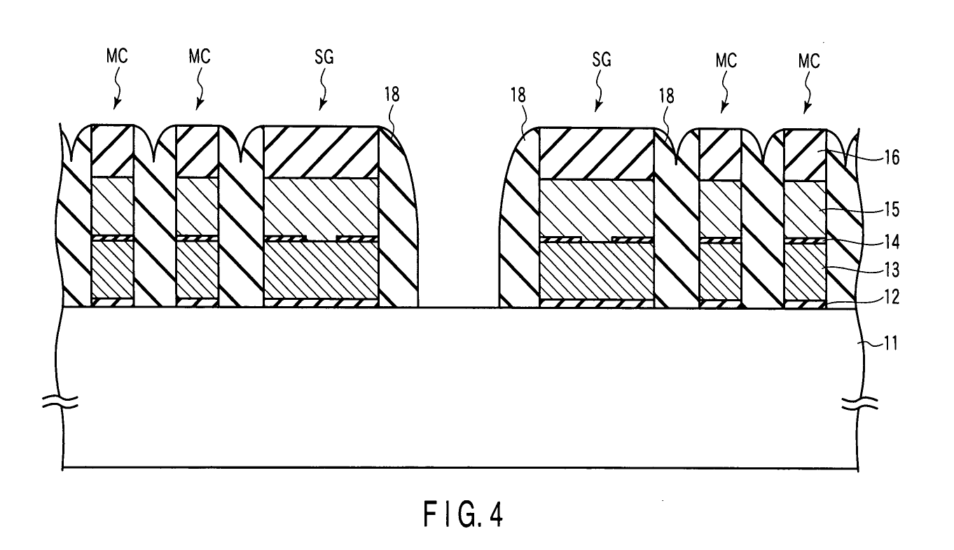

Next, as shown in FIG. 4, the oxide film 18 is etched back by the RIE method, for example, and left behind on the sidewalls of the stacked gate structures.

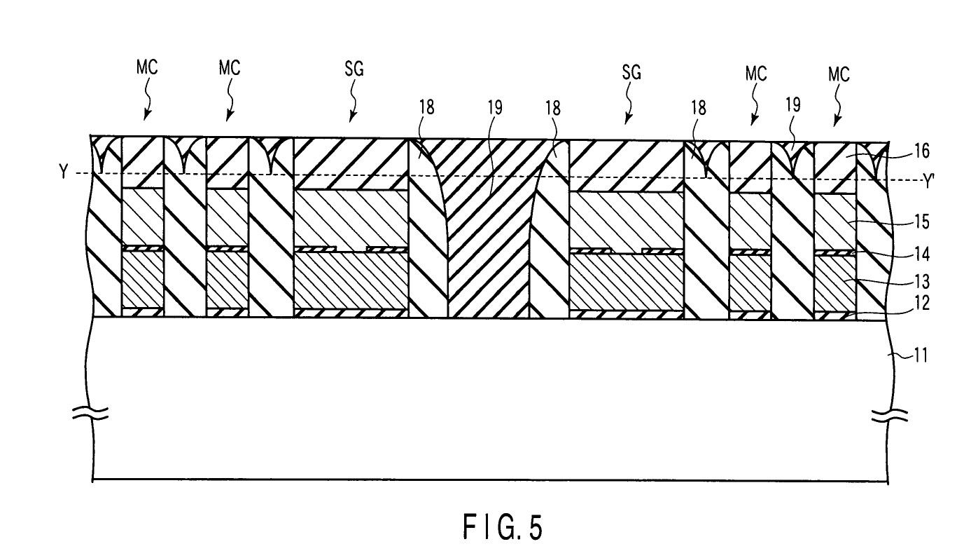

After the oxide film 18 is etched back, an interlayer insulating film 19 is formed on the entire surface to fill in between the control gate electrodes and between the select gates. Then, the surface of the resultant structure is made flat by the CMP method to eliminate step differences as shown in FIG. 5. At this time, the nitride films 16 are used as a CMP stopper.

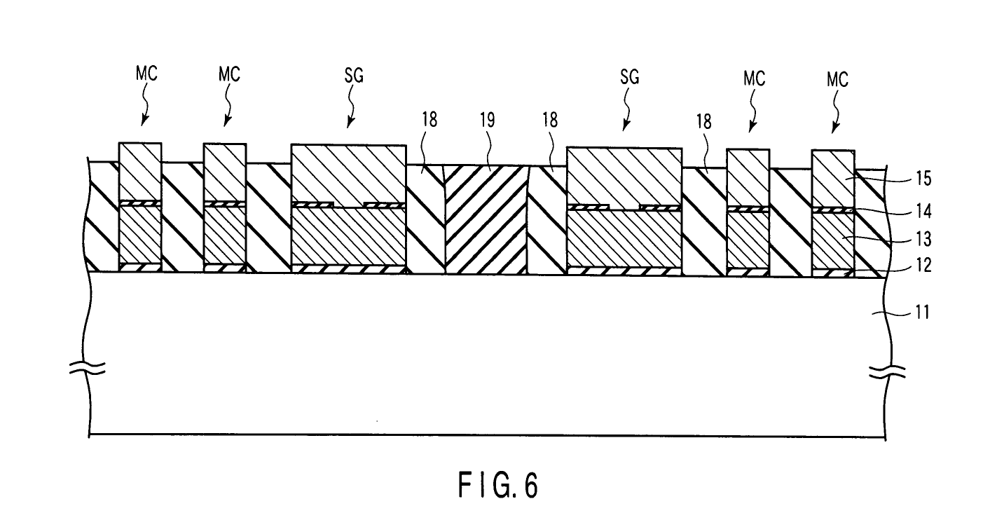

Next, as shown in FIG. 6, the nitride films 16 and interlayer insulating film 19 are etched back by use of the RIE method to expose the surfaces of the control gates 15. Since the interlayer insulating film 19 is a normal oxide film and it is necessary to etch back different types of films such as the nitride film and oxide film in the above step, it is necessary to perform the etching process in a condition that the selective etching ratio is set as low as possible.

The step is performed to expose the surfaces (upper surfaces) of the control gates 15 but it is indispensable to form silicide electrodes in a later step. Further, when the surfaces of the control gates 15 are exposed by the RIE method, it is necessary to make long the RIE process time so as not to leave the nitride films 16. Therefore, as shown in FIG. 6, it is inevitable to make the uppermost portion of the oxide film 18 which is filled in between the word lines (control gates 15) lower than the uppermost portion of the control gate 15.

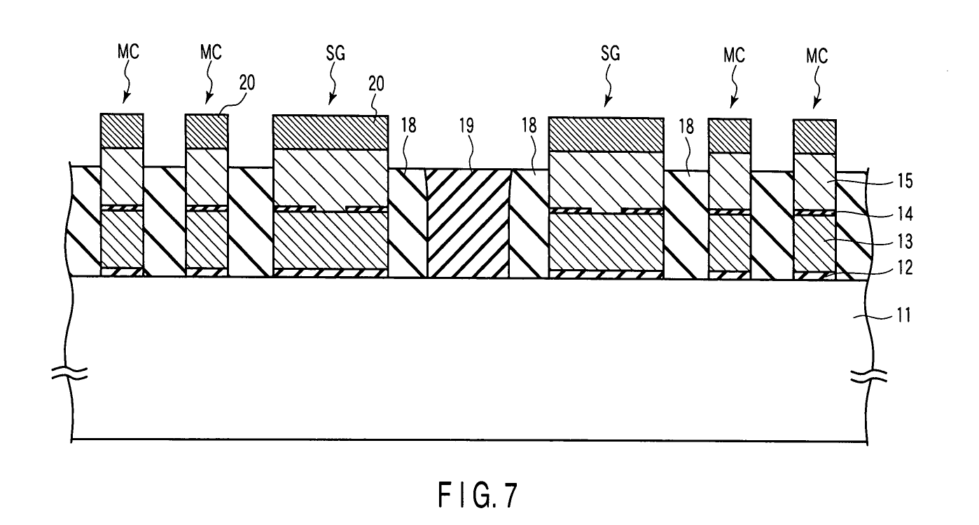

After the control gates 15 are exposed as described above, silicide electrodes 20 are formed to lower the resistances of the control gates 15 as shown in FIG. 7. For formation of the silicide electrodes 20, a sputtering method is used. First, the surfaces of the control gates 15 are exposed and then a target material to obtain a desired electrode material is sputtered and heated. As a result, metal materials attached to the control gates 15 react with the control gates 15 to form silicide electrodes 20 only in portions where Si is exposed. In this step, as a preprocess of a normal sputtering process, the preprocess is performed by use of a hydrofluoric acid-series chemical, but the preprocess accelerates a fall in the oxide films 18 between the word lines.

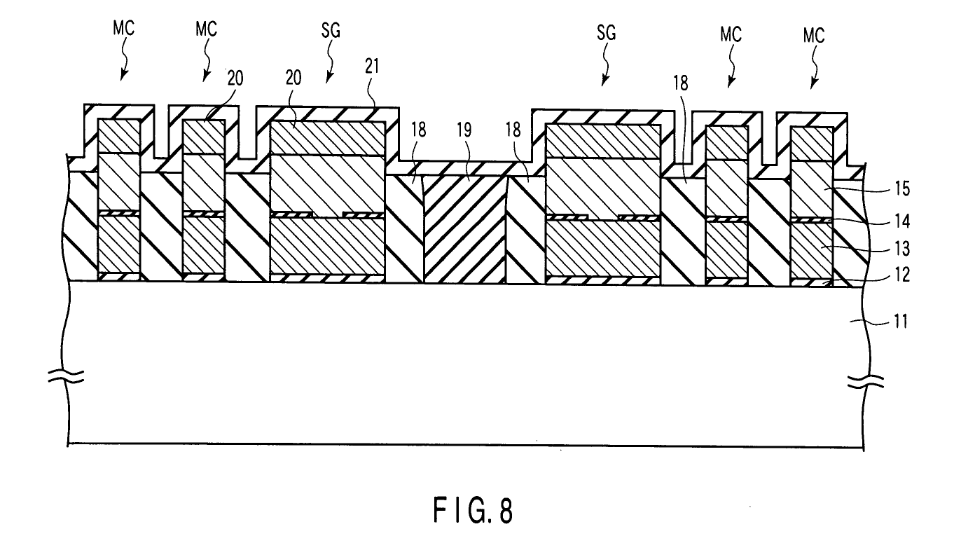

After this, a nitride film 21 is formed on the entire surface to block water contained in the films and doping of impurities in a later process (refer to FIG. 8). As a result, the structure in which the nitride film 21 is disposed between the upper portions of the control gates 15 is obtained. In addition, if the upper portion of each void which occurs when the oxide film 18 is insufficiently filled in the step of FIG. 3) formed between the control gates 15 is opened when the RIE process is performed to expose the surfaces of the control gates 15, the nitride film 21 will be inserted into the void.

Thus, if the nitride film 21 is present between the control gates 15, line capacitance between the word lines gives an influence to a variation in the potential of the word line. Further, there occurs a possibility that a current leak will occur by an electric field applied between the word lines. Therefore, a bad influence may be exerted on the device operation. In addition, the influence by the current leak caused by the electric field applied between the word lines and the line capacitance between the word lines becomes larger as the device is further miniaturized.

Therefore, in a semiconductor device and a manufacturing method thereof according to the embodiment of this invention, in order to reduce the line capacitance between the word lines and current leak, the gate structure is formed in which the uppermost portion of oxide films which are each filled in between the word lines is set higher than the uppermost portion of control gates and the same nitride film is continuously formed on the control gates and the upper surfaces and sidewalls of the oxide films.

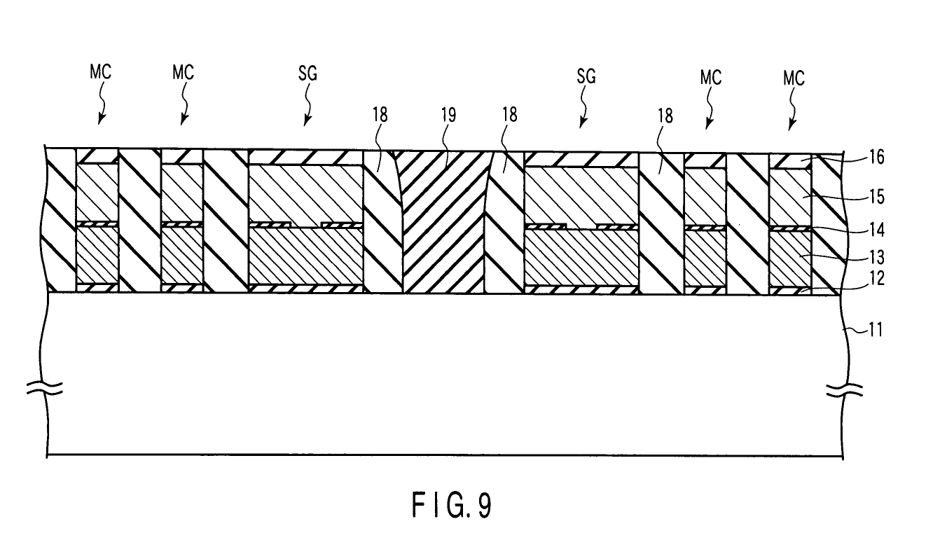

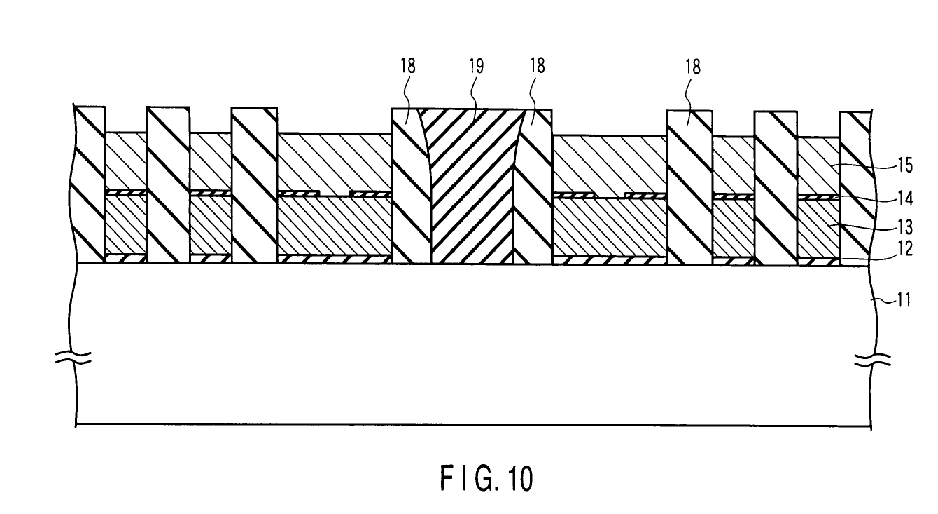

That is, in the semiconductor device and the manufacturing method thereof according to the present embodiment, the etch-back process of nitride films 16 and oxide films 18 and 19 are performed to the lowest end (indicated by the broken lines Y-Y′ in FIG. 5) of the interlayer insulating films 19 between the control gates 15 by use of the RIE method after the step shown in FIG. 5, so as to leave the nitride films 16 (refer to FIG. 9). Then, the nitride films 16 are removed by use of a phosphoric acid-series chemical, for example, hot phosphoric acid which can remove the nitride film at the high selective ratio with respect to the oxide film to expose the upper surfaces of the control gates 15 as shown in FIG. 10. In this example, since the chemical is used to etch the nitride film at the high selective ratio with respect to the oxide film, the oxide films 18 lying between the control gates 15 are hardly etched.

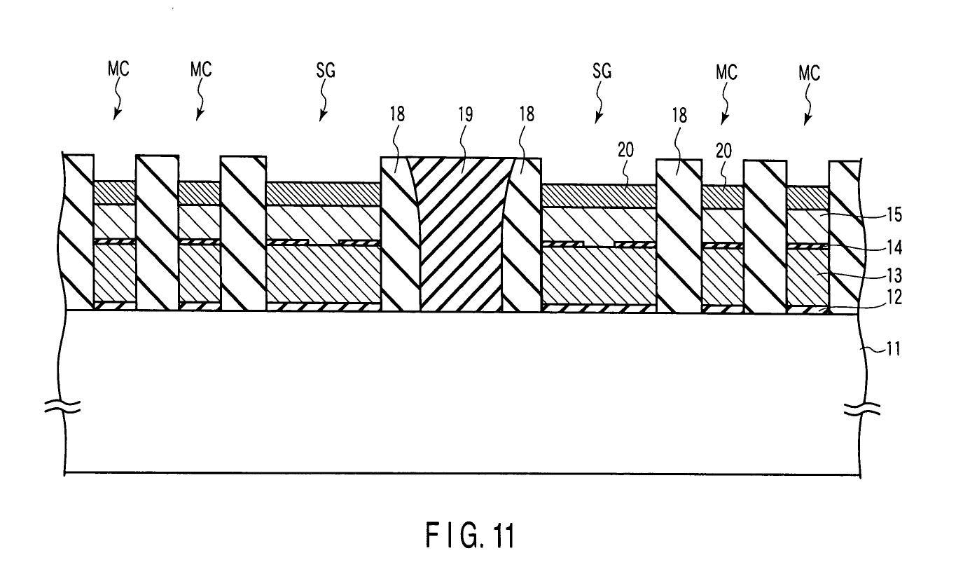

Next, silicide electrodes 20 are formed on the exposed control gates 15 (FIG. 11). The silicide electrodes 20 are formed by a sputtering method. That is, a target material to obtain a desired electrode material is sputtered and heated and metal materials attached to the control gates 15 react with the control gates 15 to form silicide electrodes only in portions where Si is exposed. In this step, a fall in the oxide films 18 each lying between the word lines can be suppressed by performing a preprocess by use of a hydrofluoric acid-series chemical. Thus, the gate structure in which the upper surfaces of the oxide films 18 between the control gates 15 are set higher than the uppermost portions of the control gates 15 can be attained.

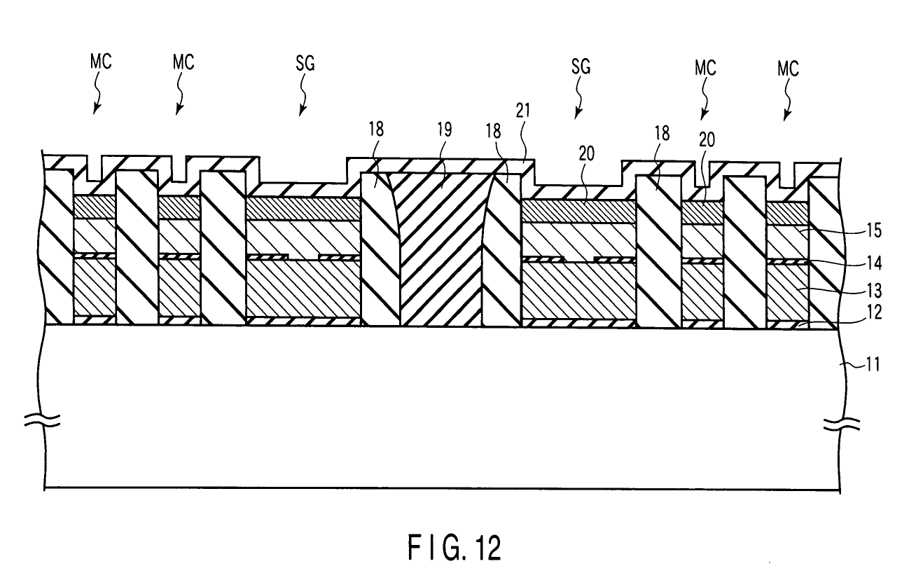

After this, a nitride film 21 is formed on the entire surface as shown in FIG. 12.

After the above step, various known manufacturing steps such as a step of forming bit lines and upper-layer wirings, a step of forming a surface protection film and a step of mounting the resultant structure into a package are performed to complete a NAND flash memory.

As described above, according to the gate structure and the manufacturing method according to the embodiment of this invention, the effects 1 to 3, below, can be obtained.

(1) Since the nitride film 21 is not inserted into between the word lines, the line capacitance between the word lines can be reduced and a write delay can be reduced.

(2) Since the nitride film 21 is not present beside the floating gate, the interference between the adjacent cells at the write time and erase time can be alleviated and erroneous writing due to a shift in the threshold voltage can be suppressed.

(3) Since the nitride film 21 is not inserted into between the word lines, current leaks between the word line and the select gate and between the word lines at the write time can be prevented.

As described above, according to one aspect of this invention, a semiconductor device and a manufacturing method thereof capable of attaining a high operation speed and high-integration density to cope with a next generation can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
first and second gate electrodes arranged adjacent to each other, each of the first and second gate electrodes having a stacked gate structure obtained by laminating a first insulating film, charge storage layer, second insulating film and control gate on a semiconductor substrate,
an oxide film which is formed between the first and second gate electrodes and whose uppermost surface is set higher than an uppermost surface of the control gate, and
a nitride film formed on the control gates, an upper surface of the oxide film and exposed sidewalls of the oxide film.

2. The semiconductor device according to claim 1, further comprising a first select gate electrode which is arranged adjacent to one of the first and second gate electrodes on the semiconductor substrate and has a stacked gate structure which is substantially the same as that of each of the first and second gate electrodes and in which the charge storage layer is electrically connected to the control gate via an opening formed in the second insulating film, and a second select gate electrode which is arranged adjacent to the first select gate electrode on the semiconductor substrate and has a gate structure which is substantially the same as that of the first select gate electrode.

3. The semiconductor device according to claim 2, wherein the oxide film is formed between one of the first and second gate electrodes and the first select gate electrode and between the first and second select gate electrodes with the uppermost surface thereof set higher than the uppermost surface of the control gate.

4. The semiconductor device according to claim 3, further comprising an interlayer insulating film filled on the semiconductor substrate and on the oxide film between the first and second select gate electrodes with an uppermost surface thereof set higher than the uppermost surface of the control gate.

5. The semiconductor device according to claim 4, wherein the nitride film is formed to extend over the control gates of the first and second select gate electrodes, the upper surface of a portion of the oxide film which lies between one of the first and second gate electrodes and the first select gate electrode, exposed sidewalls of the portion of the oxide film, upper surfaces of the interlayer insulating film and a portion of the oxide film which lies between the first and second select gate electrodes and exposed sidewalls of the portion of the oxide film.

6. The semiconductor device according to claim 1, further comprising active regions and element isolation regions alternately arranged in a direction intersecting a direction in which the first and second gate electrodes are arranged, the adjacent ones of the active regions being electrically isolated by the element isolation region.

7. The semiconductor device according to claim 2, in which the first and second select gate electrodes are arranged in a direction parallel to the first and second gate electrodes and which further comprises active regions and element isolation regions alternately arranged in a direction intersecting a direction in which the first and second select gate electrodes and the first and second gate electrodes are arranged, the adjacent ones of the active regions being electrically isolated by the element isolation region.

8. The semiconductor device according to claim 1, which further comprises silicide electrodes respectively formed on the control gates and in which the nitride film is formed on the silicide electrodes.

9. The semiconductor device according to claim 2, which further comprises silicide electrodes respectively formed on the control gates of the first and second gate electrodes and the control gates of the first and second select gate electrodes and in which the nitride film is formed above the control gates of the first and second gate electrodes and the control gates of the first and second select gate electrodes.

10. A manufacturing method of a semiconductor device comprising:
forming element isolation regions and active regions on a main surface of a semiconductor substrate,
sequentially laminating a first insulating film, first conductive layer, second insulating film, second conductive layer and first nitride film on the active regions of the semiconductor substrate,
forming a mask on the first nitride film and patterning the first nitride film, second conductive layer, second insulating film, first conductive layer and first insulating film to form a plurality of gate electrodes of gate electrode structures each having the first insulating film, charge storage layer, second insulating film, control gate and first nitride film sequentially stacked on the semiconductor substrate,
forming an oxide film on the plurality of gate electrodes and between the plurality of gate electrodes,
etching back the oxide film until surfaces of the first nitride films are exposed,
forming an interlayer insulating film on the oxide films and first nitride films,
making flat the surface to a depth until portions of the interlayer insulating film which lie between the plurality of gate electrodes are removed,
removing the first nitride films by use of a chemical having a higher selective ratio with respect to the oxide films to expose surfaces of the control gates and set uppermost surfaces of the interlayer insulating film and oxide films higher than uppermost surfaces of the control gates, and
forming a second nitride film on the first nitride films and upper surfaces and sidewalls of the oxide films.

11. The manufacturing method of the semiconductor device according to claim 10, wherein the sequentially laminating the first insulating film, first conductive layer, second insulating film, second conductive layer and first nitride film on the active regions includes forming openings in the second insulating film after the second insulating film is formed and before the second conductive layer is formed, and the forming the plurality of gate electrodes of the gate electrode structures includes forming select gate electrodes in areas in which the openings are formed.

12. The manufacturing method of the semiconductor device according to claim 10, wherein the etching back the oxide film until the surfaces of the first nitride films are exposed is etching back the oxide film by use of an RIE method and leaving the oxide films on sidewalls of the stacked gate structures.

13. The manufacturing method of the semiconductor device according to claim 10, wherein the making flat the surface to the depth until the portions of the interlayer insulating film which lie between the plurality of gate electrodes are removed is performed by use of the CMP method with the nitride films used as a stopper.

14. The manufacturing method of the semiconductor device according to claim 10, further comprising forming silicide electrodes on surfaces of the exposed control gates after the setting the uppermost surfaces of the interlayer insulating film and oxide films higher than the uppermost surfaces of the control gates and before the forming the second nitride film on the first nitride films and the upper surfaces and sidewalls of the oxide films.

15. The manufacturing method of the semiconductor device according to claim 14, wherein the forming the silicide electrodes is performed by use of a sputtering method.

16. The manufacturing method of the semiconductor device according to claim 14, wherein the forming the silicide electrodes on the surfaces of the exposed control gates includes performing a preprocess by using a hydrofluoric acid-series chemical.

17. The manufacturing method of the semiconductor device according to claim 10, further comprising forming bit lines and upper-layer interconnects, forming a surface protection film on the bit lines and upper-layer interconnects and mounting a resultant structure into a package after the forming the second nitride film.
